(19) United States
(12) Patent Application Publication
(10) Pub. No.: US 2021/0225836 A1
(43) Pub. Date: Jul. 22, 2021

(54) Electronic Device Including a High Electron Mobility Transistor and a Diode

(71) Applicant: Semiconductor Components Industries, LLC, Phoenix, AZ (US)

(72) Inventors: Jaume Roig-Guitart, Oudenaarde (BE); Samir Mouhoubi, Oudenaarde (BE)

(73) Assignee: Semiconductor Components Industries, LLC, Phoenix, AZ (US)

(21) Appl. No.: 16/748,483

(22) Filed: Jan. 21, 2020

(51) Int. Cl. H01L 27/06; H01L 29/20; H01L 29/205; H01L 29/16; H01L 29/36; H01L 29/861; H01L 29/778

(52) U.S. Cl. CPC H01L 27/0629; H01L 29/2003; H01L 29/205; H01L 29/7786; H01L 29/36; H01L 29/8611; H01L 29/16

(57) ABSTRACT

An electronic device including a die including a diode including a semiconductor base material that includes a Group 14 element and a high electron mobility transistor over the semiconductor layer, wherein the high electron mobility transistor is coupled to the diode. In an embodiment, the die can include an insulating layer under the semiconductor layer. In another embodiment, the diode can be a lateral diode. In still another embodiment, the die can include an isolation region that isolates cathode or anode electrode of the diode from each of the current-carrying electrodes of the high electron mobility transistor. In a further embodiment, the die can include an electrical connection that is configured so that the diode is in a blocking state when the high electron transistor is in a conducting state, and the diode is in a conducting state when the high electron transistor is in a blocking state.

### FIELD OF THE DISCLOSURE

The present disclosure relates to electronic devices, and more particularly to, electronic devices that include high electron mobility transistors and diodes.

### RELATED ART

A circuit can have a diode coupled to a source or drain of a transistor. The integration of a silicon-based transistor and diode is relatively easy because a pn junction can be formed within an active region shared with the silicon-based transistor. Unlike silicon-based transistors, high electron mobility transistors do not have pn junctions within the active region. A diode can be in the form of a gated diode that can have an identical structure as a high electron mobility transistor except the gate and source are electrically connected. Such an arrangement significantly adds to the area occupied by the combination of the diode and the high electron mobility transistor. Alternatively, the diode and the high electron mobility transistor can be on different die; however, such an arrangement can significantly increase area occupied by the combination on a circuit board or a printed wiring board. Further improvement to reduce area occupied by the combination of the high electron mobility transistor is desired.

### BRIEF DESCRIPTION OF THE DRAWINGS

Embodiments are illustrated by way of example and are not limited in the accompanying figures.

FIG. 1 includes an illustration of a cross-sectional view of a portion of a workpiece that includes a substrate and layers overlying the substrate.

FIG. 2 includes an illustration of a cross-sectional view of a portion of the workpiece of FIG. 1 after forming an isolation region, a doped region within a semiconductor layer, and electrodes for a high electron mobility transistor and a diode within the semiconductor layer in accordance with an embodiment.

FIG. 3 includes an illustration of a cross-sectional view of a portion of the workpiece of FIG. 1 after forming an isolation region, a doped region within a semiconductor layer, and electrodes for a high electron mobility transistor and a diode within the semiconductor layer in accordance with another embodiment.

FIG. 4 includes an illustration of a cross-sectional view of a portion of the workpiece of FIG. 1 after forming an isolation region, a doped region within a semiconductor layer, and electrodes for a high electron mobility transistor and a diode within the semiconductor layer in accordance with still another embodiment.

FIG. 5 includes an illustration of a cross-sectional view of a portion of the workpiece of FIG. 1 after forming an isolation region, a doped region within a semiconductor layer, and electrodes for a high electron mobility transistor and a diode within the semiconductor layer in accordance with a further embodiment.

FIG. 6 includes an illustration of a cross-sectional view of a portion of the workpiece of FIG. 1 after forming a doped region extending through the insulating layer and forming an isolation region, a doped region within a semiconductor layer, and electrodes for a high electron mobility transistor and a diode within the semiconductor layer in accordance with another embodiment.

FIG. 7 includes an illustration of a cross-sectional view of a diode and a high electron mobility transistor, wherein the high electron mobility transistor includes interdigitated drain, gate, and source electrodes in accordance with an embodiment.

FIG. 8 includes an illustration of a cross-sectional view of a diode and a high electron mobility transistor, wherein the high electron mobility transistor includes a plurality of drain and gate electrodes in accordance with another embodiment.

FIG. 9 includes a diagram of a single boost power factor correction circuit.

FIG. 10 includes a cross-sectional view of an exemplary physical design for a diode and a high electron mobility transistor that can be used in the circuit of FIG. 9.

FIG. 11 includes a diagram of a single boost power factor correction circuit.

FIG. 12 includes a cross-sectional view of an exemplary physical design for diodes and high electron mobility transistors that can be used in the circuit of FIG. 11.

FIG. 13 includes a diagram of a dual boost power factor correction circuit.

FIG. 14 includes a depiction of a portion of the circuit of FIG. 13 to illustrate locations of isolation regions and electrical connections.

FIG. 15 includes a diagram of a totem-pole boost power factor correction circuit.

FIG. 16 includes a depiction of a portion of the circuit of FIG. 15 to illustrate locations of isolation regions and electrical connections.

FIG. 17 includes a diagram of the circuit of FIG. 16 and an illustration of a cross-section view of the diode and the high electron mobility transistor of FIG. 16 to illustrate current flow when the high electron mobility transistor is in an off-state.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

Group numbers correspond to columns within the Periodic Table of Elements based on the IUPAC Periodic Table of Elements, version dated Nov. 28, 2016.

The term “compound semiconductor” is intended to mean a semiconductor material that includes at least two different elements. Examples include SiC, SiGe, GaN, InP, Al_{w}Ga_{(1-w)}N where 0≤w≤1, CdTe, and the like. A III-V semiconductor material is intended to mean a semiconductor material that includes at least one trivalent metal element and at least one Group 15 element. A III-N semiconductor material is intended to mean a semiconductor material that includes at least one trivalent metal element and nitrogen. A Group 13-Group 15 semiconductor material is intended to mean a semiconductor material that includes at least one Group 13 element and at least one Group 15 element.

The term “high voltage,” with reference to a layer, a structure, or a device, means that such layer, structure, or device can withstand at least 100 V difference across such layer, structure, or device (e.g., between a source and a drain of a transistor when in an off-state) without exhibiting dielectric breakdown, avalanche breakdown, or the like.

The term “lateral” refers to a direction that is parallel with a primary surface of a die. The term “vertical” refers to a direction that is perpendicular with a primary surface of a die. Features that are laterally spaced apart may or may not have a vertical (also called a z-axis) offset, and features that are vertically spaced apart may or may not have a lateral (also called an x-axis or a y-axis) offset.

The term “semiconductor base material” refers to the principal material within a semiconductor substrate, region, or layer, and does not refer to any dopant within the semiconductor substrate, region, or layer. A B-doped Si layer has Si as the semiconductor base material, and a C-doped GaN layer has GaN as the semiconductor base material.

The term “voltage rating,” with reference to an electronic device, means a nominal voltage that the electronic device is designed to withstand. For example, a transistor with a voltage rating of 50 V is designed for a 50 V difference between drain and source regions or electrodes or collector and emitter regions or electrodes when the transistor is in an off-state. The transistor may be able to withstand a higher voltage, such as 60 V or 70 V, for a limited duration, such as during and shortly after a switching operation, without significantly permanently damaging the transistor.

For clarity of the drawings, certain regions of device structures, such as doped regions or dielectric regions, may be illustrated as having generally straight line edges and precise angular corners. However, those skilled in the art understand that, due to the diffusion and activation of dopants or formation of layers, the edges of such regions generally may not be straight lines and that the corners may not be precise angles.

The terms “on,” “overlying,” and “over” may be used to indicate that two or more elements are in direct physical contact with each other. However, “over” may also mean that two or more elements are not in direct contact with each other. For example, “over” may mean that one element is above another element, but the elements do not contact each other and may have another element or elements in between the two elements.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about,” “approximately,” or “substantially” is intended to mean that a value of a parameter is close to a stated value or position. However, minor differences may prevent the values or positions from being exactly as stated. Thus, differences of up to ten percent (10%) (and up to twenty percent (20%) for semiconductor doping concentrations) for the value are reasonable differences from the ideal goal of exactly as described.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

Embodiments as described herein are useful for the integration of a transistor and a diode having different semiconductor base materials where an electrode of the diode is coupled to the transistor and the other electrode of the diode is coupled to another part of a circuit. The diode can be a freewheeling diode that can be used in a power factor correction (PFC) or other circuit. In an embodiment, the transistor can be a high electron mobility transistor (HEMT) that includes a III-V semiconductor base material, and the diode can include a Group 14 semiconductor base material. The transistor-diode combination is useful in energy conversion circuits, circuits that include an inductor having energy dissipated via the diode when the transistor is turned off, or other similar circuits. The diode can be a lateral diode that can be incorporated without a substantial increase in area occupied by the combination of the transistor and the diode. Many different physical designs are described, and other embodiments may be used while using the concepts as described herein. A particular physical design can be selected by a device designer to meet the needs or desires for a particular application.

In an aspect, an electronic device can include a die including an insulating layer; a semiconductor layer overlying the insulating layer and having a semiconductor base material that includes a Group 14 element; a lateral diode including the semiconductor layer; and a high electron mobility transistor over the semiconductor layer, wherein the high electron mobility transistor is coupled to the lateral diode.

In another aspect, an electronic device can include a die including a first electrode, a second electrode, a diode having a semiconductor base material that includes a Group 14 element, a high electron mobility transistor having a first current-carrying electrode and a second current-carrying electrode, and an isolation region. The diode can have an anode region and a cathode region, wherein the first electrode can be electrically connected to one of the anode region and the cathode region, and the second electrode can be electrically connected to the other of the anode region and the cathode region. The high electron mobility transistor can be coupled to the diode. The isolation region can isolate the first electrode from each of the first current-carrying electrode of the high electron mobility transistor and the second current-carrying electrode of the high electron mobility transistor.

In a further aspect, an electronic device can include a die including a diode within a semiconductor layer and having a semiconductor base material that includes a Group 14 element; a high electron mobility transistor overlying the semiconductor layer, and an electrical connection between the diode and the high electron mobility transistor. The electrical connection can be configured such that when the high electronic mobility transistor is in an on-state, the diode is in a blocking state, and the high electron transistor is in a conducting state, and, when the high electronic mobility transistor is in an off-state, the diode is in a conducting state, and the high electron transistor is in a blocking state.

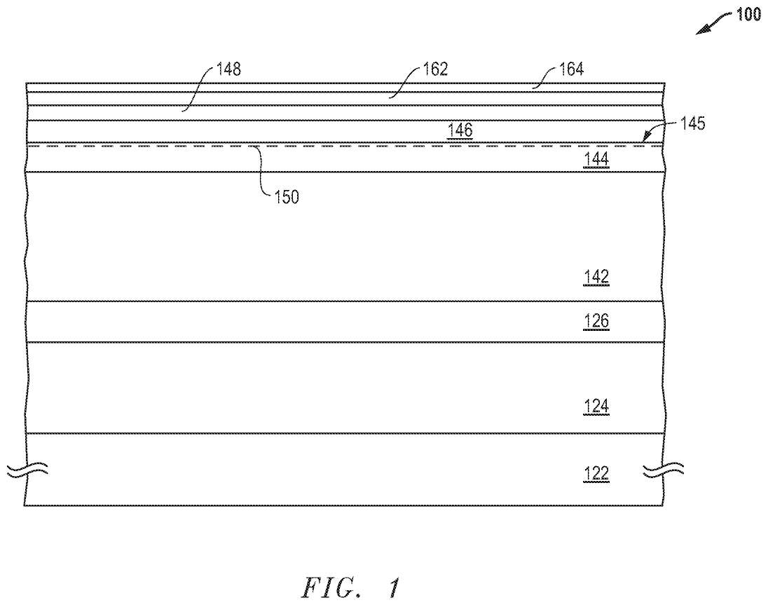

FIG. 1 includes a cross-sectional view of a portion of a workpiece 100 that can include a plurality of electronic devices that can be later singulated into die, at least one of which will include a HEMT and a diode. The HEMT can be an enhancement-mode transistor or a depletion mode transistor. The HEMT can include a III-V channel layer. The diode may be a pn junction diode within a semiconductor base material that includes a Group 14 element. Other electronic components can be formed on the same die as the HEMT and diode; however, such other components are not illustrated within cross-sectional views of the workpiece 100.

In the embodiment as illustrated in FIG. 1, the workpiece 100 includes a substrate 122, an insulating layer 124, and a semiconductor layer 126. Each of the substrate 122 and the semiconductor layer 126 can be monocrystalline and include a semiconductor base material that includes a Group 14 element. The semiconductor base material can include Si, Ge, SiC, SiGe, or the like. The substrate 122 and the semiconductor layer 126 can include the same semiconductor base material or different semiconductor base materials. The substrate 122 can be n-type doped or p-type doped and have a dopant concentration of at least 1×10¹⁸ atoms/cm³. More details regarding the semiconductor layer 126 are described after describing the insulating layer 124.

The insulating layer 124 can be formed as a buried oxide layer. In an embodiment, an oxygen implant can be used to form the insulating layer 124. In another embodiment, the substrate 122 and another substrate may have oxide layers formed along exposed surfaces and then be joined using high temperature and pressure. Most of the other substrate can be removed to leave the semiconductor layer 126. The thickness of the insulating layer 124 may depend on the voltage rating of the electronic device being formed. The electronic device can have a voltage rating in a range from 200 V to 1.2 kV. In an embodiment, the insulating layer 124 has a thickness sufficient to vertically sustain the voltage rating of the electronic device. In an embodiment, the insulating layer 124 has a thickness of at least 2 microns.

The electronic device as described herein can be well suited for a voltage rating in a range of 200 V to 1.2 kV. The thickness of the semiconductor layer 126 (tₛₑₘᵢ) may depend on the thickness of the insulating layer 124 and the voltage rating of the electronic device when the substrate 122 is electrically connected to the drain of the HEMT. In an embodiment, tₛₑₘᵢ can be at most 1.0 micron thick. As the thickness of the insulating layer 124 increases, tₛₑₘᵢ can be increased.

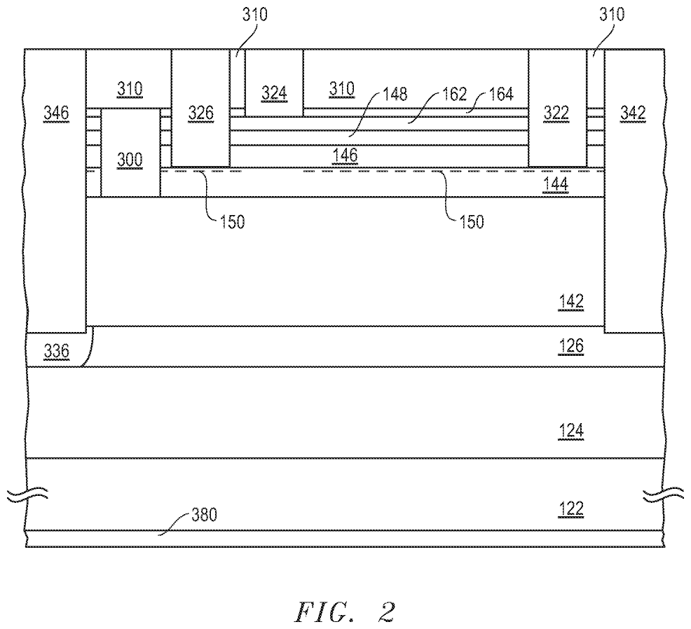

The semiconductor layer 126 can include the diode and provide a voltage drop between a subsequently formed electrode of the diode and the pn junction of the diode. Referring briefly to FIG. 2, the portion of semiconductor layer 126 to the right of the doped region 336 helps to reduce the voltage between the anode electrode 342 and the pn junction as the doped region 336. Effectively, the portion of the semiconductor layer 126 to the right of the doped region 336 can act as a resistor. The resistance of the portion of the semiconductor layer 126 between the right of the doped region 336 and the anode electrode 342 is a function of tₛₑₘᵢ (previously described), the average dopant concentration of the portion of the semiconductor layer 126, and the distance between the doped region 336 and the anode electrode 342. The distance between the doped region 336 and the anode electrode 342 is described below with respect to the distance between the gate electrode 324 and drain electrode 322 and the voltage rating of the electronic device.

A product of tₛₑₘᵢ times the average dopant concentration of the portion of the semiconductor layer 126 (“Na”) may or may not be adjusted with the voltage rating of the electronic device. In an embodiment, the product of tₛₑₘᵢ and Na may be substantially constant as the voltage rating of the electronic device changes. As tₛₑₘᵢ decreases, Na can increase, and as tₛₑₘᵢ increases, Na can decrease. In an embodiment, the product of tₛₑₘᵢ and Na can be in a range from 1×10¹¹ atoms/cm² to 1×10¹³ atoms/cm², such as 1×10¹² atoms/cm². In another embodiment, Na can be in a range from 1×10¹⁶ atoms/cm³ to 1×10¹⁷ atoms/cm³.

Na and tₛₑₘᵢ may not be limited to the design considerations previously described. Thus, in a further embodiment, tₛₑₘᵢ may be at least 1.0 micron thick, Na may be outside the limits previously described, or both.

The semiconductor layer 126 can be formed as a doped layer or may be formed as an undoped layer and subsequently doped before a subsequent layer is formed over the semiconductor layer 126 or before only a portion, and not all, of the semiconductor layer 126 is doped. As formed, the semiconductor layer 126 can be n-type doped or p-type doped and have an average dopant concentration of less than 1×10¹⁸ atoms/cm³. In the embodiment as illustrated, the semiconductor layer 126 is p-type doped and has an average dopant concentration as previously described with respect to Na. The average dopant concentration of the portion of the semiconductor layer 126 to the right of the doped region 336 is referred to herein as the background dopant concentration.

Referring to FIG. 1, the workpiece 100 can further include a buffer layer 142, a channel layer 144, a barrier layer 146, and a passivation layer 148. Although not illustrated, a nucleating layer may be formed over the semiconductor layer 126 and before forming the buffer layer 142. The nucleation layer can help to epitaxially grow subsequent layers. In an embodiment, the nucleation layer may include one or more elements that are common to the subsequently formed buffer layer 142. In a particular embodiment, the nucleation layer can include AlN when the buffer layer 142 includes an Al-containing film in contact with the nucleating layer. The thickness of the nucleating layer can be in a range of 20 nm to 1000 nm.

The buffer layer 142 can include a III-N material, and in a particular embodiment, include AlₐGa₍₁₋ₐ₎N, where 0≤a≤1. The composition of the buffer layer 142 may depend on the composition of the channel layer 144 and the voltage rating of the electronic device. The composition of the buffer layer 142 can be changed as a function of thickness, such that the buffer layer 142 has a relatively greater aluminum content closer to the semiconductor layer 126 and relatively greater gallium content closer to the channel layer 144. In a particular embodiment, the cation (metal atoms) content in the buffer layer 142 near the semiconductor layer 126 can be 10 atomic % to 100 atomic % Al with the remainder Ga, and the cation content in the buffer layer 142 near the channel layer 144 can be 0 atomic % to 50 atomic % Al with the remainder Ga. In another embodiment, the buffer layer 142 can include a plurality of films. The buffer layer 142 can have a thickness in a range of approximately 1 micron to 5 microns.

The channel layer 144 is formed over the buffer layer 142 and can include a monocrystalline compound semiconductor material. In an embodiment, the channel layer 144 can include a Group 13-N material, such as AlₓGa₍₁₋ₓ₎N, wherein 0≤x≤0.1. In a particular embodiment, the channel layer 144 includes GaN (in the prior formula, x=0). The channel layer 144 may have a thickness in a range from 10 nm to 2000 nm. A primary surface 145 can be defined by the upper surface of the channel layer 144.

The barrier layer 146 can include a III-V semiconductor material, such as a III-N semiconductor material. In an embodiment, the barrier layer 146 can include Al_{y}In_{z}Ga_{(1-y-z)}N, wherein 0≤y≤1.0, 0≤z≤0.3, and 0<(y+z)≤1. The barrier layer 146 may have a lower Ga content as compared to the channel layer 144. In a further embodiment, at least a portion of the barrier layer 146 may be doped with a p-type dopant that may improve contact resistance; however, the lower contact resistance may come with an increase of the sheet resistance associated with a two-dimensional electron gas (2DEG) 150 at the interface between the channel layer 144 and the barrier layer 146.

The barrier layer 146 can include a single film or a plurality of films. When the barrier layer 146 includes a plurality of films, the aluminum content can remain substantially the same or increase as distance from the channel layer 144 increases. As the aluminum content in the barrier layer 146 increases, the thickness of the barrier layer 146 may be relatively thinner. In an embodiment, the barrier layer 146 has a thickness of at least 10 nm, and in another embodiment, the barrier layer 146 has a thickness of at most 150 nm. In a particular embodiment, the barrier layer 146 has a thickness in a range from 20 nm to 90 nm.

Each of the channel layer 144 and the barrier layer 146 may be undoped or unintentionally doped. Unintentional doping may occur due to reactions involving the precursors during formation of the layers 144 and 146. In an embodiment, acceptors can include carbon from a source gas (e.g., Ga(CH₃)₃) when metalorganic chemical vapor deposition (MOCVD) is used to form the channel and barrier layers 144 and 146. Thus, some carbon can become incorporated as the layers 144 and 146 are grown, and such carbon can result in unintentional doping. The carbon content may be controlled by controlling the deposition conditions, such as the deposition temperature and flow rates. In an embodiment, each of the channel and barrier layers 144 and 146 has a carrier impurity concentration that is greater than 0 and less than 1×10¹⁴ atoms/cm³ or less than 1×10¹⁵ atoms/cm³ and in another embodiment, at most 1×10¹⁶ atoms/cm³. In a further embodiment, the carrier impurity concentration with unintentional doping is in a range from 1×10¹³ atoms/cm³ to 1×10¹⁶ atoms/cm³. The channel layer 144 and the barrier layer 146 can have substantially the same dopant concentration or significantly different dopant concentrations.

The buffer layer 142, the channel layer 144, and barrier layer 146 are formed using an epitaxial growth technique, and thus, the barrier layer 146, the channel layer 144, and at least a portion of the buffer layer 142 can be monocrystalline. In a particular embodiment, metal-containing films can be formed using metalorganic chemical vapor deposition.

The passivation layer 148 can be formed over the barrier layer 146 and include a silicon nitride. The passivation layer 148 can be deposited at a temperature in a range of 1000° C. to 1150° C. In an embodiment, the passivation layer 148 can have a thickness in a range of 5 nm to 40 nm. In another embodiment, the passivation layer 148 can be deposited at a different temperature or have a thickness outside the range described above.

In an embodiment as illustrated in FIG. 1, an enhancement-mode transistor having a gate dielectric layer 162 is being formed. The gate dielectric layer 162 can include a silicon dioxide, a silicon nitride, an aluminum oxide, a zirconium oxide, a hafnium oxide, a niobium oxide, another suitable gate dielectric material, or any combination thereof and have a thickness in a range from 2 nm to 20 nm. A capping layer 164 can be used to protect the gate dielectric layer 162. The capping layer 164 can include silicon nitride and have a thickness in a range of approximately 20 nm to 500 nm. The gate dielectric layer 162 and the capping layer 164 can be formed using a chemical or physical vapor technique.

In another embodiment (not illustrated), an enhancement mode HEMT can include a p-type semiconductor gate member. The gate member can be formed on the barrier layer 146 and include a p-type semiconductor material, such as p-type Al_{w}Ga_{(1-w)}N, wherein 0≤w≤1. The p-type dopant in the gate member can include Mg, C, or the like. In an embodiment, the average dopant concentration in the gate member can be in a range from 1×10¹⁸ atoms/cm³ to 1×10²¹ atoms/cm³. The gate member can have a thickness in a range from 2 nm to 200 nm. In a further embodiment (not illustrated), a depletion-mode HEMT may be formed. In each of these embodiments, the gate dielectric layer 162 and the capping layer 164 may be omitted. More details regarding gate electrodes for the alternatively embodiments are described later in this specification. The previously described thickness for the passivation layer can be used for a depletion-mode transistor.

FIG. 2 includes an illustration after further processing. An isolation region 300 can be formed so that the 2DEG 150 is discontinuous between a source electrode 326 and a cathode electrode 346. The isolation region 300 can be formed by etching to define an opening that extends through at least the barrier layer 146. In the embodiment as illustrated, the opening extends through the channel layer 144 and may or may not extend into the buffer layer 142. The opening can be filled with an electrically insulating material to form the isolation region 300.

An interlevel dielectric (ILD) layer 310 can be formed over the passivation layer 148 and the isolation region 300. The ILD layer 310 can include a single film or a plurality of films. The single film or each of the films can include an oxide, a nitride, or an oxynitride. In an embodiment, the ILD layer 310 can have a thickness in a range from 20 nm to 2000 nm.

Electrodes for the electronic device can be formed. Design considerations for different voltage rating are briefly addressed before continuing the description of the formation of the electrodes. The spacing between the drain electrode 322 and the gate electrode 324 can be adjusted for different voltage ratings. For example, a smaller voltage rating, such as 200 V, can allow a drain-to-gate spacing to be relatively smaller, and a higher voltage rating, such as 1.2 kV, can have a relatively larger drain-to-gate spacing. The spacing between the anode electrode 342 and the cathode electrode 346 can change with the drain-to-gate spacing. The spacing between the anode electrode 342 and the cathode electrode 346 may be increased or decreased by substantially the same amount as an increase or a decrease in drain-to-gate spacing. For example, an electronic device can be designed for a particular voltage rating and have a drain-to-gate spacing of 25 microns and a spacing between the anode electrode 342 and the cathode electrode 346 of 35 microns. At a higher voltage rating, the drain-to-gate spacing may be increased by 5 microns to 30 microns. In an embodiment, the spacing between the anode electrode 342 and the cathode electrode 346 can be increased by substantially the same amount, and for this example, the increase is 5 microns. Thus, the spacing between the anode electrode 342 and the cathode electrode 346 can be 40 microns. In another embodiment, the change in the spacing between the anode electrode 342 and the cathode electrode 346 can be significantly different from the change in the drain-to-gate spacing. The change in the spacing between the anode electrode 342 and the cathode electrode 346 helps to ensure the voltage across pn junction of the diode when reversed biased is not too high. In the particular embodiments described within the paragraph, the product of the thickness and background dopant concentration of the semiconductor layer 126 does not need to be changed.

The order of formation of electrodes, their corresponding openings, or the electrodes and the openings may be selected to meet the needs or desires for a particular application. The description below addresses the anode electrode 342 and the cathode electrode 346 before addressing the drain electrode 322 and source electrode 326. The gate electrode 324 is described after the other electrodes.

In an embodiment, many layers are patterned to define openings for the anode electrode 342 and the cathode electrode 346. The openings for the anode electrode 342 and the cathode electrode 346 can extend through the layers 142, 144, 146, 148, and 310 to the semiconductor layer 126. The portion of the semiconductor layer 126 at the bottom of the opening for the cathode electrode 346 can be implanted to form the doped region 336 that is a cathode region of the diode. The doped region 336 has a conductivity type opposite the conductivity type of the portion to the semiconductor layer 126 to the right of the doped region 336, wherein such portion is an anode region of the diode. In an embodiment, the doped region 336 can be doped with an n-type dopant and have a dopant concentration of at least 1×10¹⁹ atoms/cm³ to allow an ohmic contact to be formed with the cathode electrode 346.

The portion of the semiconductor layer 126 along the opening for the anode electrode 342 may or may not be further doped. If the portion is not further doped, a Schottky contact can be formed where the anode electrode 342 contacts the semiconductor layer 126 that is lightly doped. In another embodiment (not illustrated), the portion of the semiconductor layer 126 along the opening for the anode electrode 342 can be further doped to form a doped region similar to the doped region 336 except that the conductivity region for the portion near the anode electrode 342 is the same as the conductivity type as the semiconductor layer 126. Thus, such portion can be p-type doped when the semiconductor layer 126 is doped. In still another embodiment, the contact can be a merged contact in which the anode electrode 342 contacts the semiconductor layer 126 and a more heavily doped p-type region along an edge of the contact opening. In still another embodiment, the doping to form the doped region 336 and a doped region near the anode electrode 342 may be performed earlier in the process flow, for example, after forming the semiconductor layer 126 and before forming the buffer layer 142.

A conductive layer can be deposited over the ILD layer 310 and within the openings for the anode electrode 342 and the cathode electrode 346. The conductive layer can include a single film or a plurality of films. In an embodiment, the conductive layer can include an adhesion film and a barrier film. Such films may include Ta, TaSi, Ti, TiW, TiSi, TiN, or the like. The conductive layer can further include a conductive bulk film. The bulk film can include Al, Cu, or another material that is more conductive than other films within the conductive layer. In an embodiment, the bulk film can include at least 90 wt. % Al or Cu. The bulk film can have a thickness that is at least as thick as the other films within the conductive layer. In an embodiment, the bulk film has a thickness in a range from 20 nm to 900 nm and, in a more particular embodiment, in a range from 50 nm to 500 nm. More or fewer films can be used in the conductive layer. The number and composition of the films within the conductive layer can depend on the needs or desires for a particular application. After reading this specification, skilled artisans will be able to determine the composition of the conductive layer that is tailored to their devices. The conductive layer is patterned to complete formation of the anode electrode 342 and the cathode electrode 346.

The ILD layer 310 can be patterned to define contact openings for the drain electrode 322 and the source electrode 326. The contact openings for the drain and source electrodes 322 and 326 can extend through the ILD layer 310 and the passivation layer 148. In an embodiment, the contact openings for the drain and source electrodes 322 and 326 can extend through part, but not all, of the thickness of the barrier layer 146. In another embodiment, the contact openings for the drain and source electrodes 322 and 326 can land on the barrier layer 146 or extend through all of the thickness of the barrier layer 146 and contact the channel layer 144.

A conductive layer can be deposited over the ILD layer 310 and within the openings for the drain electrode 322 and the source electrode 326. The conductive layer can have any of the compositions and thicknesses as previously described with respect to the conductive layer for the anode electrode 342 and the cathode electrode 346. The conductive layers may have the same number of films or a different number of films, the same material or different materials, and the same thickness or significantly different thicknesses. The conductive layer is patterned to complete formation of the drain electrode 322 and the source electrode 326.

The ILD layer 310 can be patterned to define a contact opening for the gate electrode 324. The contact openings for the gate electrode 324 can extend through the ILD layer 310 and the capping layer 164 and contact the gate dielectric layer 162.

Another conductive layer can be deposited over the ILD layer 310 and within the opening and patterned to form the gate electrode 324. The conductive layer can have any of the compositions and thicknesses as previously described with respect to the conductive layer for the anode electrode 342 and the cathode electrode 346. The conductive layers may have the same number of films or a different number of films, the same material or different materials, and the same thickness of different thicknesses. A portion of the conductive layer that contacts the gate dielectric layer 162 can affect the work function for the HEMT. Thus, the conductive layer for the gate electrode 342 may have a different composition as compared to the conductive layer for the drain and source electrodes 322 and 326 or the conductive layer for the anode and cathode electrodes 342 and 346. The conductive layer for the gate electrode 324 is patterned to complete formation of the gate electrode 324.

One or more additional interconnector levels and a passivation layer (not illustrated) can be formed to form a substantially completed device. One or more field electrodes (not illustrated) can be formed that are electrically connected to any one or more of the drain electrode 322, gate electrode 324, or the source electrode 326. A field electrode coupled to the drain electrode 322 can extend laterally toward the gate electrode 324, and each field electrode coupled to the source electrode 326 or the gate electrode 324 can extend toward the drain electrode 322. The field electrodes can help to control electrical fields within the HEMT.

After a backgrind operation to reduce the thickness of the substrate 122, a backside metal 380 can be formed along an exposed surface of the substrate 122. The backside metal 380 may be deposited or attached to the substrate 122.

In a finished device, the HEMT is coupled to the diode within the semiconductor layer 126. The couplings between the HEMT and the diode can depend on the particular application. In an embodiment, the drain electrode 322 and the anode electrode 342 can be electrically connected to each other, and the source electrode 326 and the cathode electrode 346 can be coupled to different parts of a circuit. In another embodiment, the drain electrode 322 can be electrically connected to the cathode electrode 346, or the source electrode can be electrically connected to the anode electrode 342. In such an embodiment, the physical design of the electronic device can be changed so that the doped region 336 is moved from the left-hand side of FIG. 2 to the right-hand side of FIG. 2. The conductive member to the right of the drain electrode 322 will be the cathode electrode 346, and the conductive member to the left of the source electrode 326 will be the anode electrode 342. As will be described with respect to further embodiments, the backside metal 380 may be electrically connected to the drain electrode 322, the source electrode 326, the anode electrode 342, or the cathode electrode 346. In a particular embodiment, an electrode for the HEMT and an electrode for the diode can be electrically connected to the backside metal 380. Some alternative embodiments regarding the physical design will be addressed before addressing particular circuits that include the HEMT and diode.

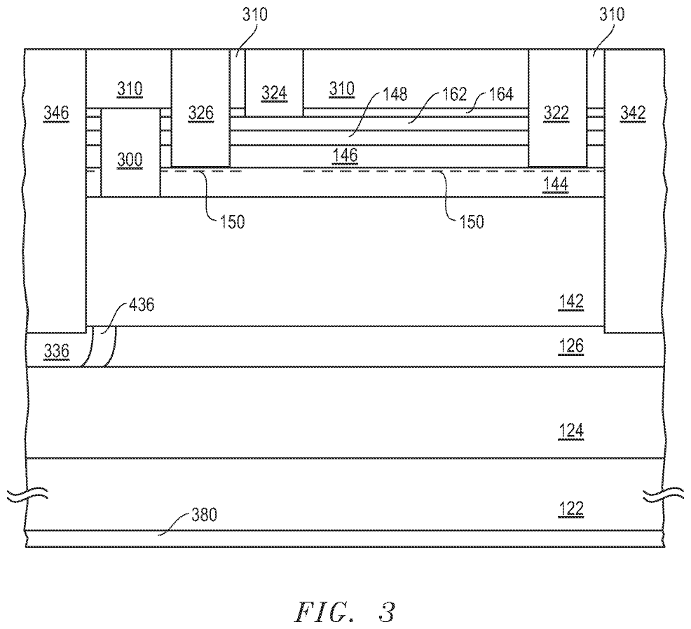

FIG. 3 includes an illustration of another set of embodiments, in which a graded junction is used for the cathode region of the diode. The cathode region of the diode includes the doped region 336 and a relatively lightly doped region 436. Both doped regions have the same conductivity type that is opposite the conductivity type of the semiconductor layer 126 to the right of the doped region 436. The average dopant concentration of the lightly doped region 436 will be between the average dopant concentration of the doped region 336 and the background dopant concentration of the semiconductor layer 126. In an embodiment, the lightly doped region 436 can have an average dopant concentration in a range from 2×10¹⁶ atoms/cm³ to 5×10¹⁷ atoms/cm³. The doped region 436 can extend beyond the doped region 336 by a distance in a range of 0.05 micron to 2.0 microns. In other embodiments, the average dopant concentration of the doped region 436 and the distance can be different from those previously described.

The doped regions 336 and 436 can be formed during the same process sequence or different process sequence. For example, doped regions 336 and 436 can be formed after defining the opening for the cathode electrode 346. The implants for the doped regions 336 and 436 can be performed, where a dopant for the doped region 436 can diffuse within the semiconductor layer 126 at a higher rate as compared to a dopant for the doped region 336. For example, the doped region 336 can include As, and the doped region 436 can include P. A diffusion operation can be performed to diffuse the dopants to form the doped regions 336 and 436 before the cathode electrode 346 is formed. In another embodiment, one or both of the doped regions 336 and 436 can be formed before forming the buffer layer 142 over the semiconductor layer 126. The border between the doped regions 336 and 436 is along a line corresponding to a dopant concentration that is halfway between the peak dopant concentrations of the doped regions 336 and 436.

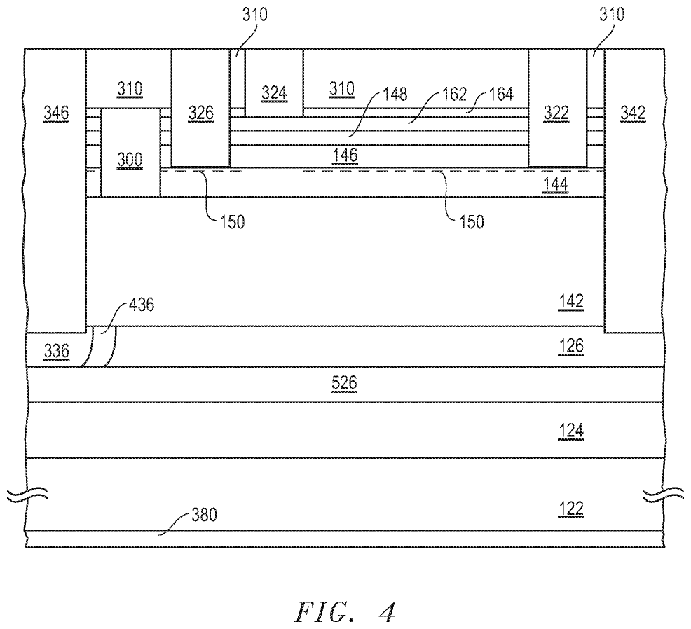

FIG. 4 includes another embodiment in which another semiconductor layer 526 can help to provide an additional charge balance. The embodiment as illustrated in FIG. 4 is modified from the embodiment illustrated with respect to FIG. 3. In another embodiment, the semiconductor layer 526 may be used with any of the embodiments as illustrated with respect to FIGS. 2 and 5 to 8. The semiconductor layer 526 has an opposite conductivity type as compared to the semiconductor layer 126. Other than the dopant, the semiconductor layer 526 can have any of the compositions, average dopant concentrations, and thicknesses of the semiconductor layer 126. The semiconductor layers 126 and 526 can include the same semiconductor material or different semiconductor materials, substantially the same average dopant concentration or significantly different average dopant concentrations, and substantially the same thickness or significantly different thicknesses.

The semiconductor layers 126 and 526 can be formed from a semiconductor layer having a thickness corresponding to the thicknesses of the semiconductor layers 126 and 526 and a conductivity type and an average doping concentration that is the same as the semiconductor layer 526. An upper portion of the relatively thicker semiconductor layer can be doped to result in the semiconductor layer 126. A lower portion of the relatively thicker semiconductor layer is the semiconductor layer 526. In this particular embodiment, the average dopant concentration of the semiconductor layer 126 can be higher than the semiconductor layer 526. In another embodiment, dopants can be changed during growth of the semiconductor layers 126 and 526. For example, an n-type dopant may be used when growing the semiconductor layer 526, and then the n-type dopant may be stopped, and a p-type dopant started when growing the semiconductor layer 126. In this embodiment, the background dopant concentration of the semiconductor layer 126 may be substantially the same as the average dopant concentration of the semiconductor layer 526 or may be significantly higher or lower than the average dopant concentration of the semiconductor layer 526.

The doped regions 336 and 436 can be formed as previously described. The doped region 436 extends to the semiconductor layer 526 to allow the semiconductor layer 526 to be biased using the cathode electrode 346.

FIG. 5 includes an illustration in which the cathode electrode 646 extends through the insulating layer 124 to the substrate 122. Such an embodiment can allow for current extraction through the backside metal 380. The configuration is illustrated as modified from the embodiment as illustrated in FIG. 3. In another embodiment, the configuration can be modified from the embodiments as illustrated in FIGS. 2, 4, 7, and 8. The formation of the opening for the cathode electrode 646 may depend on when the doped regions 336 and 436 are formed. When the doped regions 336 and 436 are formed before the buffer layer 142, the opening for the cathode electrode 646 can be formed during a single etch sequence without any intervening doping step. In another embodiment, one or both of the doped regions 336 and 436 can be formed after forming the buffer layer 142. In such an embodiment, the opening for the cathode electrode 646 can be formed during different etch sequences. The first etch sequence can be performed to form an opening similar to the opening for the cathode electrode 346 in FIGS. 2 to 4. The dopant for either or both of the doped regions 336 and 436 can be implanted and diffused into the semiconductor layer 126. During a second etch sequence, the opening is extended to reach the substrate 122. A conductive layer can be deposited and patterned to form the cathode 646. The conductive layer for the cathode electrode 646 can have any of the compositions as previously described with respect to the cathode electrode 346.

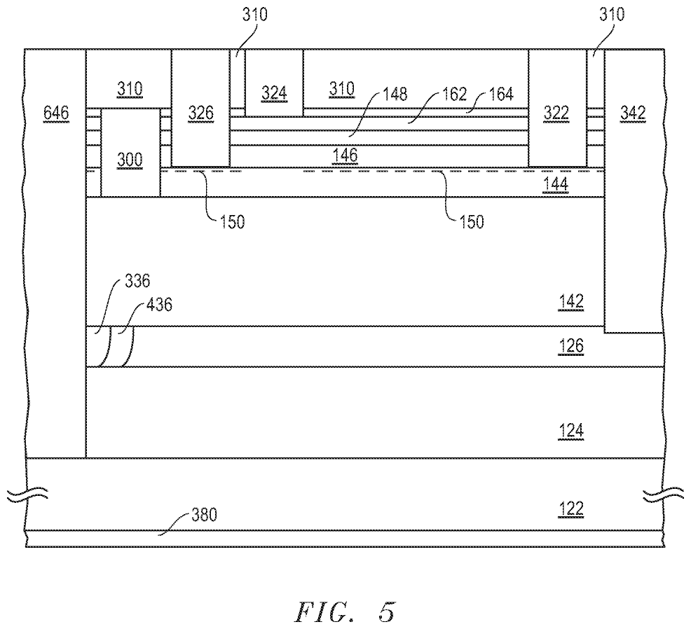

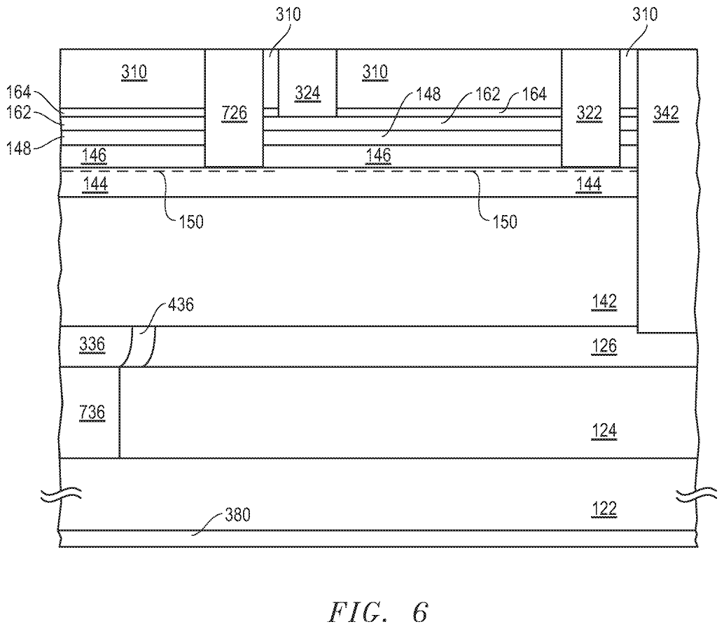

FIG. 6 illustrates another embodiment in which a top-side cathode electrode is not used. The configuration is illustrated as modified from the embodiment as illustrated in FIG. 3. In another embodiment, the configuration can be modified from the embodiments as illustrated in FIGS. 2 and 4. The substrate 122 may have the same conductivity type as the doped regions 336 and 436. A heavily doped region 736 is used to electrically connect the doped regions 336 and 436. Such a configuration can allow current to be extracted using the backside metal 380. In an embodiment, the doped region 736 may be part of the substrate 122 or can be a doped portion of a semiconductor layer that includes the semiconductor layer 126. The insulating layer 124 can be selectively formed, rather than underlying all of the HEMT and diode.

In other embodiments, FIGS. 5 and 6 can be modified to allow current for the anode to flow through the backside metal 380. With respect to FIG. 5, the anode electrode 342, rather than the cathode electrode 646 extends to the substrate 122 similar to the doped region 736. With respect to FIG. 6, the anode electrode 342 may be omitted and a heavily doped region can be used to electrically connect the semiconductor layer 126 to the substrate 122. In this embodiment, the substrate 122, the semiconductor layer 126, and the heavily doped region 736 have the same conductivity type.

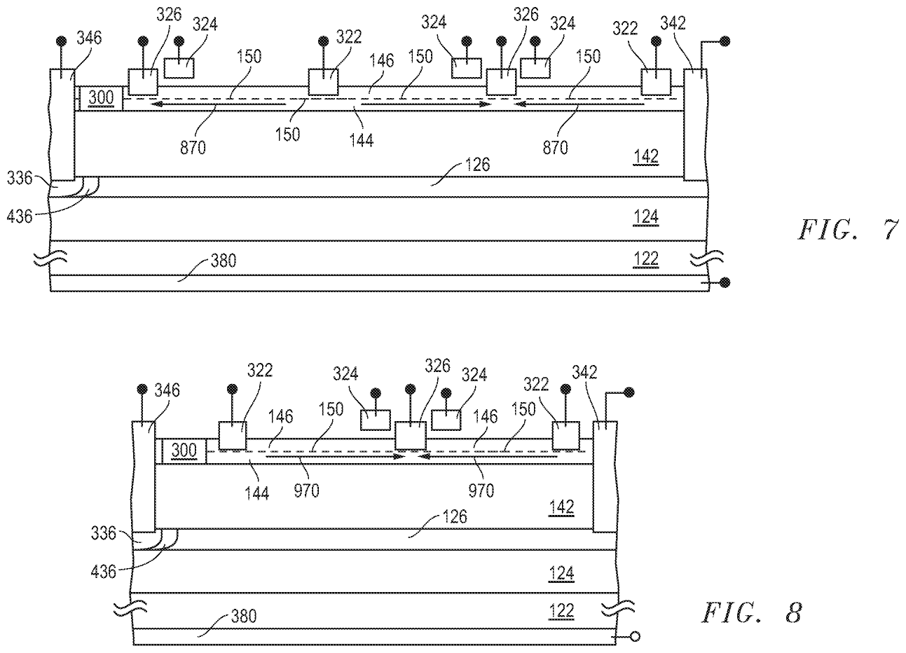

A variety of different physical designs may be used with the concepts as previously described. Cross-sectional views in FIGS. 7 to 10 and 17 are based on or modified from the physical design in FIG. 3. In further embodiments, each of the embodiments as illustrated in FIGS. 7 and 8 may be modified from the physical designs in FIGS. 2 and 4 to 6. Furthermore, the cross-sectional views in FIGS. 7 to 10 and 17 do not illustrate all layers to simplify understand the concepts as illustrated in FIGS. 7 to 10 and 17 and their corresponding descriptions. The passivation layer 148, the dielectric layer 162, the capping layer 164, and the ILD layer 310 may be present but are not illustrated in FIGS. 7 to 10 and 17.

FIG. 7 includes a design where the HEMT includes a plurality of interdigitated drain, gate, and source electrodes. Top views of a design with interdigitated electrodes can be found in FIGS. 5 and 6 in US 2019/0348410, which is incorporated herein by reference for its teachings of placement of drain, source, and gate electrodes. FIG. 7 includes a cross-sectional view that can be used for transistor structures where the electrodes can have lengths that extend into and out of FIG. 7. The anode electrode 342 is near the right-hand side, and the cathode electrode 346 and the isolation region 300 are near the left-hand side of FIG. 7. The transistor structures for the HEMT overlie the semiconductor layer 126. The design includes drain electrodes 322, gate electrodes 324, and source electrodes 326. Each of the gate electrodes 324 is closer to its corresponding source electrode 326 than its corresponding drain electrode 322. All of the drain electrodes 322 are electrically connected to one another, all of the gate electrodes 324 are electrically connected to one another, and all of the source electrodes 326 are electrically connected to one another. When the HEMT is in an on-state, current flows from the drain electrodes 322 to the source electrodes 326 as illustrated by the arrows 870 in FIG. 7. FIG. 8 includes another design where one of the drain electrodes 322 is adjacent to the isolation region 300, and single source electrode 326 is near the center of FIG. 8. When the HEMT is in an on-state, current flows from the drain electrodes 322 to the source electrodes 326 as illustrated by the arrows 970 in FIG. 8 or from the source electrode 326 to the drain electrode 322 depending whether the transistor is operating in the 3^{rd} quadrant or the 1^{st} quadrant. The embodiments as illustrated in FIGS. 7 and 8 are modified from the physical design in FIG. 3. In further embodiments, each of the embodiments as illustrated in FIGS. 7 and 8 may be modified from the physical designs in FIGS. 2 and 4 to 6.

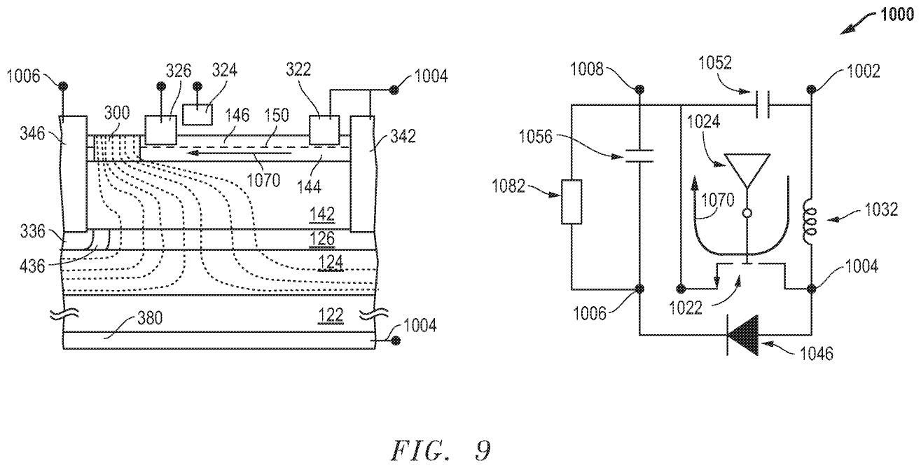

As illustrated in FIGS. 9 and 10, the physical design of the circuit 1000 can include an electrical connection, such as the electrical connection between the drain electrode 322 and the cathode electrode 346, that allows the HEMT 1022 to be in a conducting state and the diode 1046 to be in a blocking state when the electronic device is in an on-state, and allows the diode 1046 to be in a conducting state and the HEMT 1022 to be in a blocking state when the electronic device is in an off-state.

FIGS. 9 and 10 illustrate current flow through a portion of a single boost PFC circuit 1000 when the HEMT 1022 is in an on-state (FIG. 9) and when HEMT 1022 is in an off-state (FIG. 10). In the circuit 1000, an input terminal 1002 is coupled to a terminal of an inductor 1032 and an electrode of a capacitor 1052. At a switching node 1004, and the other terminal of the inductor 1032 is coupled to a drain of the HEMT 1022 and an anode of a diode 1046. A gate of the HEMT 1022 is coupled to a gate driver 1024. At a ground terminal 1008, a source of the HEMT 1022 is coupled to the other electrode of the capacitor 1052, an electrode of a capacitor 1056, and a terminal of a load resistor 1082. At an output terminal 1006, a cathode of the diode 1046 is coupled to the other terminal of the load resistor 1082 and the other electrode of a capacitor 1056.

Regarding the physical design, the drain electrode 322, the anode electrode 342, and the substrate 122 are electrically connected to the switching node 1004. In the physical designs illustrated in FIGS. 9 and 10, dashed lines correspond to equipotential lines within the physical structure.

Referring to FIG. 9, when the HEMT 1022 is in the on-state, no significantly current flows through the diode 1046, and current flows through the HEMT 1022, as illustrated with arrow 1070. The source electrode 326 is at approximately the same voltage as the ground terminal 1008, such as approximately 0 V. The gate driver 1024 provides a voltage to the gate electrode 324 of the HEMT 1022 that is higher than a threshold voltage for an enhancement-mode transistor or higher than a pinch-off voltage of a depletion mode transistor. In an embodiment having an enhancement-mode transistor, the voltage can be in a range of 1 V to 9 V and, in a particular embodiment, can be 6 V. The drain electrode 322, the anode electrode 342, the substrate 122, and the switching node 1004 are at a voltage slightly higher than the source electrode 326, and in an embodiment, can be approximately 0.1 V. The cathode electrode 346 and the output terminal 1006 can be at the designed voltage rating of the electronic device. The circuit 1000 can be designed so that the voltage difference between the output terminal 1006 and the ground terminal 1008 is in a range of 200 V to 1.2 kV. In a particular embodiment, the voltage rating can be 400 V, so the cathode electrode 346 and the output terminal 1006 are at approximately 400 V.

Referring to FIG. 10, when the HEMT 1022 is switched to the off-state, no significant current flows through the HEMT 1022, and current flows through the diode 1046, as illustrated with arrow 1170. The source electrode 326 is at approximately the same voltage as the ground terminal 1008, such as approximately 0 V. The gate driver 1024 provides a voltage to the gate electrode 324 of the HEMT 1022 that is lower than a threshold voltage for an enhancement-mode transistor or lower than a pinch-off voltage of a depletion mode transistor. In an embodiment having an enhancement-mode transistor, the voltage at the gate electrode 324 can be the same as the voltage of the source electrode 326, for example, 0 V. The drain electrode 322, the anode electrode 342, the substrate 122, and the switching node 1004 are at a voltage corresponding to a sum of the voltage at the output terminal 1006 and the threshold voltage of the diode 1046 when the diode 1046 is in a forward-bias conducting state. The threshold voltage of the diode 1046 can be in a range of 0.1 V to 0.9 V and, in a particular embodiment, is 0.3 V. Thus, when the voltage at the output node 1006 is approximately 400 V, the voltage at the switching node 1004 can be approximately 400.3 V. Current will continue to flow as illustrated in FIG. 10 until the voltage difference between the switching node 1004 and the output terminal 1006 is less than the threshold voltage of the diode 1046 when the diode 1046 is in the forward-bias conducting state.

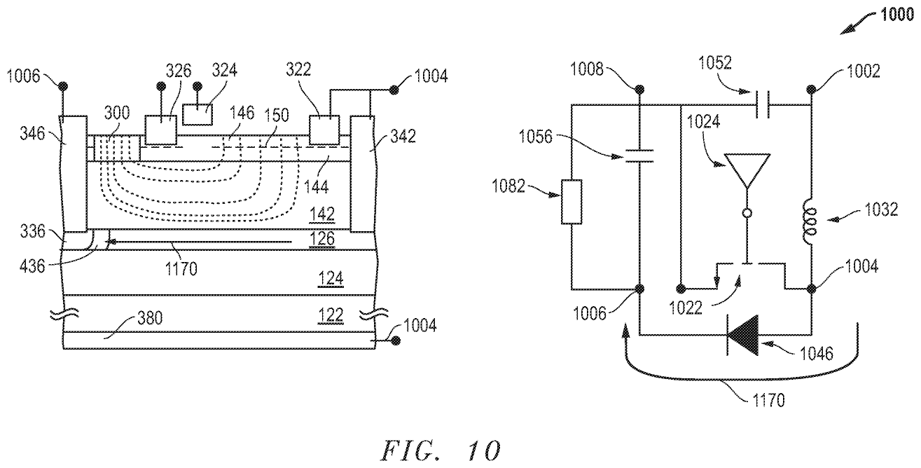

FIGS. 11 to 17 include diagrams and illustrations of electronic devices that can include combinations of HEMTs and diodes within PFC circuits. FIG. 11 includes a circuit 1200 that can be a single boost PFC circuit. The circuit 1200 has a power supply 1270 having its terminals coupled to a bridge of diodes 1211 to 1214. Cathodes of the diodes 1211 and 1213 are coupled to a terminal of an inductor 1232, and anodes of the diodes 1212 and 1214 are coupled to a source of a HEMT 1222, an electrode of a capacitor 1252, and an output terminal 1202. The other terminal of the inductor 1232 is coupled to an anode of a diode 1246 and a drain of the HEMT 1222. A cathode of the diode 1246 is coupled to the other terminal of the capacitor 1252 and another output terminal 1204. The voltage difference between the output terminals 1202 and 1204 corresponds to an output voltage.

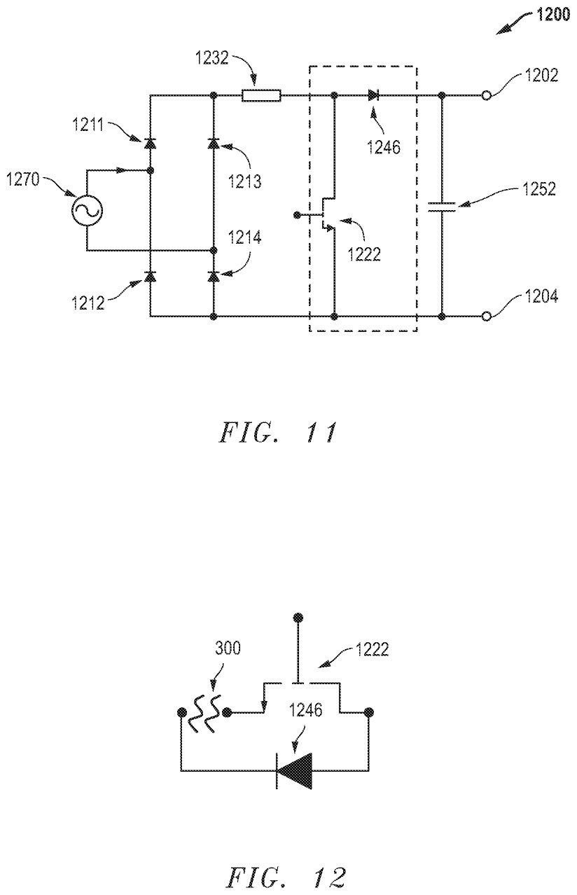

FIG. 12 corresponds to a portion of the circuit 1200 within the dashed line in FIG. 11 and includes the HEMT 1222 and the diode 1246. The drain of the HEMT 1222 is electrically connected to the anode of the diode 1246. The wavy lines between the source of the HEMT 1222 and the cathode of the diode 1246 correspond to the isolation region 300 as previously described with respect to FIG. 2. The HEMT 1222 and the diode 1246 can have any of the structures previously described with respect to the HEMTs and diodes as illustrated in FIGS. 2 to 8.

FIG. 13 includes a circuit 1400 that can be a dual boost PFC circuit. The circuit 1400 has a power supply 1470 having a terminal coupled to a cathode of a diode 1412 and a terminal of an inductor 1432. Another terminal of the power supply 1470 is coupled to a cathode of a diode 1414 and a terminal of an inductor 1434. Anodes of the diodes 1412 and 1414 are coupled to sources of HEMTs 1422 and 1424, an electrode of a capacitor 1452, and an output terminal 1404. The other terminal of the inductor 1432 is coupled to the drain of the HEMT 1422 and an anode of the diode 1446, and another terminal of the inductor 1434 is coupled to the drain of the HEMT 1424 and an anode of the diode 1448. Cathodes of the diodes 1446 and 1448 are coupled to the other electrode of the capacitor 1452 and another output terminal 1402. The voltage difference between the output terminal corresponds to an output voltage.

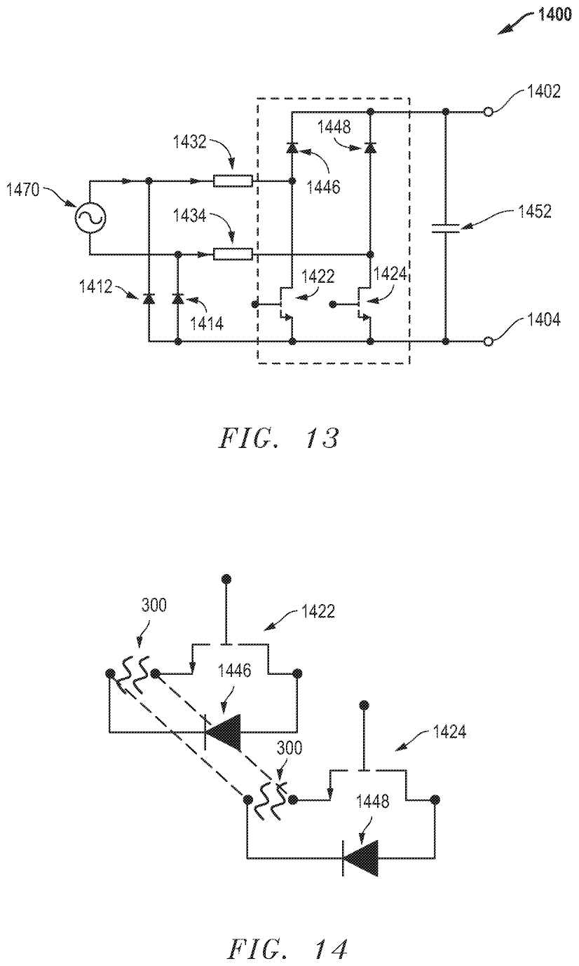

FIG. 14 corresponds to a portion of the circuit 1400 within the dashed line and includes the HEMTs 1422 and 1424 and the diodes 1446 and 1448. The drain of the HEMT 1422 is electrically connected to the anode of the diode 1446, and the drain of the HEMT 1424 is electrically connected to the anode of the diode 1448. The sources of the HEMTs 1422 and 1424 are electrically connected to each other, and the cathodes of the diodes 1446 and 1448 are electrically connected to each other. Each set of wavy lines between the source of the HEMT 1422 and the cathode of the diode 1446 and between the source of the HEMT 1424 and the cathode of the diode 1448 corresponds to the isolation region 300 as described with respect to FIG. 2. The pair of the HEMT 1422 and the diode 1446, the pair of the HEMT 1424 and the diode 1448, or both pairs can have any of the structures previously described with respect to the HEMTs and diodes as illustrated in FIGS. 2 to 8.

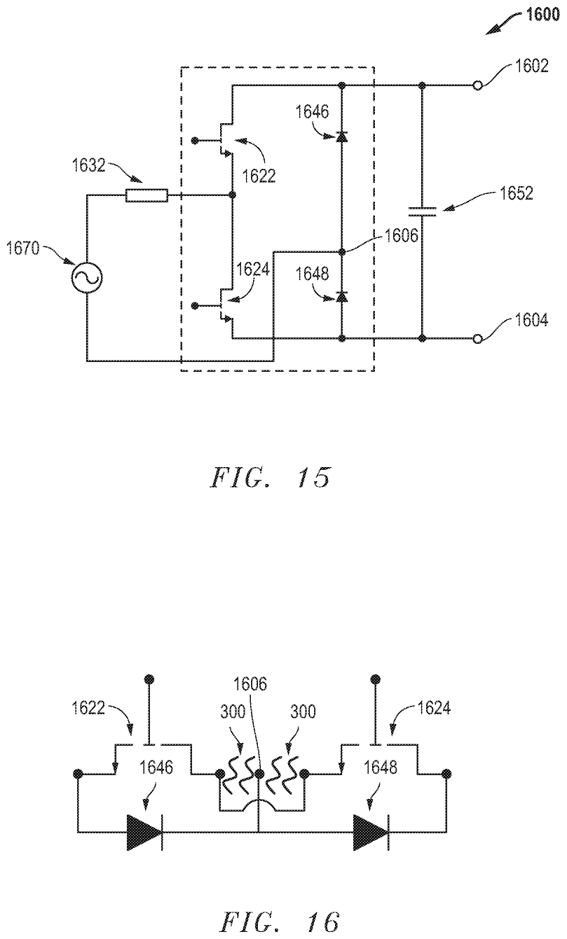

FIG. 15 includes circuit 1600 that can be a totem-pole PFC circuit. The circuit 1600 has a power supply 1670 having a terminal coupled to a terminal of an inductor 1632 and another terminal coupled to an anode of a diode 1646 and a cathode of a diode 1648 at a node 1606. The other terminal of the inductor 1632 is coupled to a source of a HEMT 1622 and a drain of a HEMT 1624. A drain of the HEMT 1622, a cathode of the diode 1646, an electrode of a capacitor 1652 are coupled to an output terminal 1602. A source of the HEMT 1624, an anode of the diode 1648, the other electrode of the capacitor 1652 are coupled to another output terminal 1604. The voltage difference between the output terminals 1602 and 1604 corresponds to an output voltage.

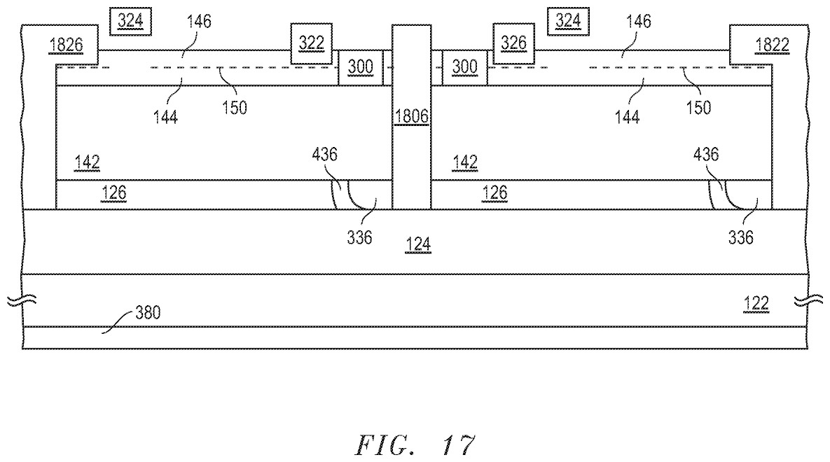

FIG. 16 corresponds to a portion of the circuit 1600 within the dashed line and includes the HEMTs 1622 and 1624 and the diodes 1646 and 1648. The drain of the HEMT 1622 is electrically connected to the anode of the diode 1646, and the drain of the HEMT 1624 is electrically connected to the anode of the diode 1648. The sources of the HEMTs 1622 and 1624 are electrically connected to each other, and the cathodes of the diodes 1646 and 1648 are electrically connected to each other. Each set of wavy lines in FIG. 15 corresponds to the isolation region 300 as described with respect to FIG. 2.

FIG. 17 includes a cross-sectional view of an exemplary physical design corresponding to the portion of the circuit 1600 as illustrated in FIG. 16. A conductive member 1822 acts as a drain electrode for the HEMT 1622 and a cathode electrode for the diode 1646. Another conductive member 1826 acts as a source electrode for the HEMT 1624 and an anode electrode for the diode 1648. A further conductive member 1806 corresponds to part of the node 1606 in FIG. 15. Doped regions 336 and 436 are adjacent to the left-hand side of each of the conductive members 1822 and 1806. The diode structures in FIG. 17 are based on the diode structure in FIG. 3. In other embodiments, any of the diode structures in FIGS. 2 and 4 to 8 may be used for either or both of the diode structures in FIG. 17. Isolation regions 300 electrically isolate the conductive member 1806 from each of the source electrode 326 of the HEMT 1622 and the drain electrode 322 of the HEMT 1624.

Embodiments as described herein are useful for the integration of a transistor and a diode having different semiconductor base materials where an electrode of the diode is coupled to the transistor and the other electrode of the diode is coupled to another part of a circuit. The diode can be a freewheeling diode that can be used in a PFC or other circuit. In an embodiment, the transistor can be a HEMT that includes a III-V semiconductor base material, and the diode can include a Group 14 semiconductor base material. The transistor-diode combination is useful in energy conversion circuits, circuits that include an inductor having energy dissipated via the diode when the transistor is turned off, or other similar circuits. The diode can be a lateral diode that can be incorporated without a substantial increase in area occupied by the combination of the transistor and the diode. Many different physical designs are described, and other embodiments may be used while using the concepts as described herein. A particular physical design can be selected by a device designer to meet the needs or desires for a particular application.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the embodiments as listed below.

Embodiment 1. An electronic device including a die can include an insulating layer; a first semiconductor layer overlying the insulating layer and having a semiconductor base material that includes a Group 14 element; a lateral diode including the first semiconductor layer; and a high electron mobility transistor over the first semiconductor layer, wherein the high electron mobility transistor is coupled to the lateral diode.

Embodiment 2. The electronic device of Embodiment 1, wherein the first semiconductor layer has a thickness and a background dopant concentration, and a product of the thickness and the background dopant concentration is in a range from 1×10¹¹ atoms/cm² to 1×10¹³ atoms/cm².

Embodiment 3. The electronic device of Embodiment 2, wherein the thickness is at most 2 microns, and the background dopant concentration is in a range from 1×10¹⁶ atoms/cm³ to 1×10¹⁷ atoms/cm³.

Embodiment 4. The electronic device of Embodiment 1, wherein the die further includes a substrate having a semiconductor base material that includes a Group 14 element, and the insulating layer is disposed between the substrate and the first semiconductor layer.

Embodiment 5. The electronic device of Embodiment 4, wherein the substrate and a drain electrode of the high electron mobility transistor are electrically coupled to each other.

Embodiment 6. The electronic device of Embodiment 1, wherein the lateral diode includes an anode region and a cathode region, the anode region includes a p-type Group 14 semiconductor material, and the cathode region includes an n-type Group 14 semiconductor material.

Embodiment 7. The electronic device of Embodiment 6, wherein the anode region of the diode is electrically connected to a drain electrode of the high electron mobility transistor.

Embodiment 8. The electronic device of Embodiment 6, wherein the high electron mobility transistor includes a channel layer overlying the first semiconductor layer; and a barrier layer overlying the channel layer.

Embodiment 9. The electronic device of Embodiment 8, wherein the die further includes an anode electrode and a cathode electrode, wherein:
the anode electrode extends through the channel layer and the barrier layer and contacts an anode region of the diode, wherein the anode region is within the first semiconductor layer, and
the cathode electrode extends through the channel layer and the barrier layer and contacts a cathode region of the diode, wherein the cathode region is within the first semiconductor layer.

Embodiment 10. The electronic device of Embodiment 9, wherein the die further includes an isolation region between the cathode electrode and a source electrode of the high electron mobility transistor.

Embodiment 11. The electronic device of Embodiment 6, wherein the cathode region includes a heavily doped region and a lightly doped region, wherein the lightly doped region laterally extends further over the insulating layer as compared to the heavily doped region.

Embodiment 12. The electronic device of Embodiment 6, wherein the die further includes an anode electrode, a cathode electrode, and a second semiconductor layer, wherein the anode electrode contacts an anode region within the first semiconductor layer and is spaced apart from and not electrically connected to the first semiconductor layer, the cathode electrode is electrically connected a cathode region that contacts the second semiconductor layer, and the second semiconductor layer is disposed between the insulating layer and the first semiconductor layer and extends laterally under the high electron mobility transistor and the anode electrode.

Embodiment 13. The electronic device of Embodiment 4, wherein the die further includes an anode electrode and a cathode electrode, wherein one of the anode electrode and the cathode electrode extends through the first semiconductor layer and the insulating layer to the substrate, and the other of the anode electrode and the cathode electrode extends to the first semiconductor layer and is spaced apart from the substrate by the insulating layer.

Embodiment 14. The electronic device of Embodiment 4, wherein the die further includes an anode electrode, a cathode electrode, and a conductive region, wherein the conductive region underlies the first semiconductor layer, extends through the insulating layer and contacts the substrate, and the other of the anode electrode and the cathode electrode extends to the first semiconductor layer and is spaced apart from the substrate by the insulating layer.

Embodiment 15. An electronic device including a die can include a first electrode, a second electrode, a diode, a high electron mobility transistor, and an isolation region. The diode can have a semiconductor base material that includes a Group 14 element, wherein the diode has an anode region and a cathode region, wherein the first electrode is electrically connected to one of the anode region and the cathode region, and the second electrode is electrically connected to the other of the anode region and the cathode region. The high electron mobility transistor can have a first current-carrying electrode and a second current-carrying electrode, wherein the high electron mobility transistor is coupled to the diode. The isolation region can isolate the first electrode from each of the first current-carrying electrode of the high electron mobility transistor and the second current-carrying electrode of the high electron mobility transistor.

Embodiment 16. The electronic device of Embodiment 15, further including an insulating layer, wherein the diode is within a semiconductor layer overlies the insulating layer, and the high electron mobility transistor overlies the semiconductor layer.

Embodiment 17. The electronic device of Embodiment 15, wherein no conductive member lies between the isolation region and each of the first electrode and the first current-carrying electrode of the high electron mobility transistor.

Embodiment 18. An electronic device including a die can include a diode, a high electron mobility transistor and an electrical connection. The diode can be within a semiconductor layer and have a semiconductor base material that includes a Group 14 element. The high electron mobility transistor can overlie the semiconductor layer. The electrical connection can be between the diode and the high electron mobility transistor. The electrical connection can be configured such that (1) when the high electronic mobility transistor is in an on-state, the diode is in a blocking state, and the high electron transistor is in a conducting state, and (2) when the high electronic mobility transistor is in an off-state, the diode is in a conducting state, and the high electron transistor is in a blocking state.

Embodiment 19. The electronic device of Embodiment 18, wherein the die further includes an insulating layer, wherein the electrical connection includes a conductive member that contacts an anode region or a cathode region of the diode and acts as a source electrode or a drain electrode of the high electron mobility transistor.

Embodiment 20. The electronic device of Embodiment 18, wherein the high electron mobility transistor has a first current-carrying electrode and a second current-carrying electrode. The die can further include a first electrode, a second electrode, and an isolation region. The first electrode can contact one of an anode region of the diode and a cathode region of the diode, and the second electrode can contact the other of the anode region and the cathode region and is electrically connected to the first current-carrying electrode of the high electron mobility transistor or the second current-carrying electrode of the high electron mobility transistor. The isolation region can isolate the first electrode and from each of the first current-carrying electrode of the high electron mobility transistor and the second current-carrying electrode of the high electron mobility transistor.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An electronic device including a die comprising:
an insulating layer;
a first semiconductor layer overlying the insulating layer and having a semiconductor base material that includes a Group 14 element;
a lateral diode including the first semiconductor layer; and
a high electron mobility transistor over the first semiconductor layer, wherein the high electron mobility transistor is coupled to the lateral diode.

2. The electronic device of claim 1, wherein the first semiconductor layer has a thickness and a background dopant concentration, and a product of the thickness and the background dopant concentration is in a range from 1×10¹¹ atoms/cm² to 1×10¹³ atoms/cm².

3. The electronic device of claim 2, wherein the thickness is at most 2 microns, and the background dopant concentration is in a range from 1×10¹⁶ atoms/cm³ to 1×10¹⁷ atoms/cm³.

4. The electronic device of claim 1, wherein the die further comprises a substrate having a semiconductor base material that includes a Group 14 element, and the insulating layer is disposed between the substrate and the first semiconductor layer.

5. The electronic device of claim 4, wherein the substrate and a drain electrode of the high electron mobility transistor are electrically coupled to each other.

6. The electronic device of claim 1, wherein the lateral diode comprises an anode region and a cathode region, the anode region includes a p-type Group 14 semiconductor material, and the cathode region includes an n-type Group 14 semiconductor material.

7. The electronic device of claim 6, wherein the anode region of the diode is electrically connected to a drain electrode of the high electron mobility transistor.

8. The electronic device of claim 6, wherein the high electron mobility transistor comprises:
a channel layer overlying the first semiconductor layer; and
a barrier layer overlying the channel layer.

9. The electronic device of claim 8, wherein the die further comprises an anode electrode and a cathode electrode, wherein:
the anode electrode extends through the channel layer and the barrier layer and contacts an anode region of the diode, wherein the anode region is within the first semiconductor layer, and
the cathode electrode extends through the channel layer and the barrier layer and contacts a cathode region of the diode, wherein the cathode region is within the first semiconductor layer.

10. The electronic device of claim 9, wherein the die further comprises an isolation region between the cathode electrode and a source electrode of the high electron mobility transistor.

11. The electronic device of claim 6, wherein the cathode region includes a heavily doped region and a lightly doped region, wherein the lightly doped region laterally extends further over the insulating layer as compared to the heavily doped region.

12. The electronic device of claim 6, wherein the die further comprises an anode electrode, a cathode electrode, and a second semiconductor layer, wherein:
the anode electrode contacts an anode region within the first semiconductor layer and is spaced apart from and not electrically connected to the first semiconductor layer,
the cathode electrode is electrically connected a cathode region that contacts the second semiconductor layer, and
the second semiconductor layer is disposed between the insulating layer and the first semiconductor layer and extends laterally under the high electron mobility transistor and the anode electrode.

13. The electronic device of claim 4, wherein the die further comprises an anode electrode and a cathode electrode, wherein:
one of the anode electrode and the cathode electrode extends through the first semiconductor layer and the insulating layer to the substrate, and
the other of the anode electrode and the cathode electrode extends to the first semiconductor layer and is spaced apart from the substrate by the insulating layer.

14. The electronic device of claim 4, wherein the die further comprises an anode electrode, a cathode electrode, and a conductive region, wherein:
the conductive region underlies the first semiconductor layer, extends through the insulating layer and contacts the substrate, and
the other of the anode electrode and the cathode electrode extends to the first semiconductor layer and is spaced apart from the substrate by the insulating layer.

15. An electronic device including a die comprising;
a first electrode;
a second electrode;
a diode having a semiconductor base material that includes a Group 14 element, wherein the diode has an anode region and a cathode region, wherein the first electrode is electrically connected to one of the anode region and the cathode region, and the second electrode is electrically connected to the other of the anode region and the cathode region;
a high electron mobility transistor having a first current-carrying electrode and a second current-carrying electrode, wherein the high electron mobility transistor is coupled to the diode; and
an isolation region that isolates the first electrode from each of the first current-carrying electrode of the high electron mobility transistor and the second current-carrying electrode of the high electron mobility transistor.

16. The electronic device of claim 15, further comprising an insulating layer, wherein:
the diode is within a semiconductor layer overlies the insulating layer, and
the high electron mobility transistor overlies the semiconductor layer.

17. The electronic device of claim 15, wherein no conductive member lies between the isolation region and each of the first electrode and the first current-carrying electrode of the high electron mobility transistor.

18. An electronic device including a die comprising:
a diode within a semiconductor layer and having a semiconductor base material that includes a Group 14 element;
a high electron mobility transistor overlying the semiconductor layer; and
an electrical connection between the diode and the high electron mobility transistor, wherein the electrical connection is configured such that:
when the high electronic mobility transistor is in an on-state, the diode is in a blocking state, and the high electron transistor is in a conducting state, and
when the high electronic mobility transistor is in an off-state, the diode is in a conducting state, and the high electron transistor is in a blocking state.

19. The electronic device of claim 18, wherein the die further comprises an insulating layer, wherein the electrical connection includes a conductive member that contacts an anode region or a cathode region of the diode and acts as a source electrode or a drain electrode of the high electron mobility transistor.

20. The electronic device of claim 18, wherein:
the high electron mobility transistor has a first current-carrying electrode and a second current-carrying electrode; and
the die further comprises:
a first electrode contacts one of an anode region of the diode and a cathode region of the diode;
a second electrode contacts the other of the anode region and the cathode region and is electrically connected to the first current-carrying electrode of the high electron mobility transistor or the second current-carrying electrode of the high electron mobility transistor; and
an isolation region that isolates the first electrode and from each of the first current-carrying electrode of the high electron mobility transistor and the second current-carrying electrode of the high electron mobility transistor.
